(19) United States
(12) Patent Application Publication
(10) Pub. No.: US 2010/0319986 A1
(43) Pub. Date: Dec. 23, 2010

(54) MODULAR VENTED CIRCUIT BOARD ENCLOSURE

(76) Inventors: Charles A. Bleau, Decatur, GA (US); Mark P. McJunkin, Atlanta, GA (US)

Correspondence Address: JOHN S. PRATT, ESQ;KILPATRICK STOCKTON, LLP, 1100 PEACHTREE STREET, SUITE 2800, ATLANTA, GA, 30309, US

(21) Appl. No.: 12/817,728

(22) Filed: Jun. 17, 2010

Related U.S. Application Data
(60) Provisional application No. 61/218,019, filed on Jun. 17, 2009.

(51) Int. Cl. H05K 5/00; B23P 19/04

(52) U.S. Cl. 174/520; 29/426.2

(57) ABSTRACT

A modular vented circuit board enclosure for housing circuit boards, computer circuitry, or other devices is disclosed. The modular enclosure can be formed by coupling together various components, such as one or more (i) side components, (ii) corner components, and (iii) face components. The modular enclosure can be easy to manufacture and be configured for a wide variety of applications, such as customizing a size and/or number of devices to be housed. For example, circuit boards can be added or removed from the enclosure without the need to cut portions of a standard rack mount. One or more components of the modular vented circuit board can be added to permit entry of more circuit boards into the enclosure.

### CROSS-REFERENCE TO RELATED APPLICATIONS

This application claims the benefit of U.S. Provisional Application No. 61/218,019, filed Jun. 17, 2009 and entitled “Modular Vented Circuit Board Enclosure,” the contents of which are incorporated herein by this reference.

### TECHNICAL FIELD

Embodiments relate to an enclosure, and more particularly, to a circuit board enclosure having modular components to accommodate a flexible number of circuit boards.

### BACKGROUND

Camera systems typically include an image-sensing device for viewing an object, and include electronic circuitry for capturing and processing the image data generated by the image-sensing device. The camera system can output the processed image data to a computer or monitor for display of the object under observation.

Manufacturers of such camera systems often have customers in a wide variety of fields. For example, camera manufacturers may build systems for applications in astronomy, medicine, biotechnology, machine vision for manufacturing, security, space or oceanic exploration, or other fields. Although camera systems may have common elements, each application requires customization of the camera system configuration. Therefore, the number and nature of the circuit boards containing the electronic circuitry may vary greatly from one system to another, depending upon the application in which it is to be used. For example, for astronomical applications observing faint phenomena in deep space, the camera system includes highly sophisticated image capture and processing components, which involves a greater number of circuit boards containing the electronic circuitry necessary to operate in this application. In comparison, for a camera system operating in a building security application, the camera system may not need to be as complex.

Camera manufacturers typically make several modifications to a standard rack mount, such as a 21 U rack mount, to accommodate the various circuit boards for a particular application. One such modification is cutting the 21 U rack mount enclosure and lid to form a 3 U rack mount for holding three circuit boards. Other modifications to a standard rack mount include cutting metric holes and rails into the enclosure and reworking the rack mount to include heating and cooling devices to control the temperature of the camera's components, such as the image sensing device and electronic circuitry. These modifications can result in additional labor and equipment expense, and can waste material—for example, the unused portions of the original rack mount.

Furthermore, later upgrades to camera systems can include modifications and, thus, can increase labor and equipment expense. In addition, users can experience a delay in using cameras because the cameras are shipped back to the manufacturer to be upgraded.

Moreover, systems other than camera systems may use a customizable number of circuit boards and experience the same or similar issues as described above. For example, a desktop computing device may need to be expanded, upgraded, or otherwise modified to include additional circuit boards, but current enclosures limit the customization or ease of customization for such expansion, upgrading, and modification.

Therefore, systems and methods are desirable that can provide a customizable enclosure for housing circuit boards for camera systems or other types of systems.

### SUMMARY

Certain aspects and embodiments of the present invention relate to a modular enclosure that is capable of being customized with respect to a number and size of circuit boards to be enclosed. In some embodiments, side components of the enclosure are added or removed to increase or decrease a size of the modular enclosure. At least one of the side components can be coupled to a corner component through one or more engagement portions. The corner component can couple to a face component through one or more engagement portions.

In one aspect, a modular enclosure for housing a circuit board is described. The modular enclosure includes a side component, a corner component, and a face component. The side component has a side component engagement portion. The corner component has a first corner component engagement portion and a second corner component engagement portion. The first corner component engagement portion can cooperate with the side component engagement portion. The face component has a face engagement portion that can cooperate with the second corner component engagement portion.

In another aspect, a modular enclosure is described. The modular enclosure includes a first side component and a second side component. The first side component includes a first engagement portion. The second side component includes a second engagement portion that can cooperate with the first engagement portion of the first side component. The first side component coupled to the second side component forms a vent for allowing airflow into and out of the enclosure. The vent has a Z-shaped cross-section.

In another aspect, a method is described for customizing a size of a modular disclosure. A first side component is decoupled from a second side component of the modular enclosure. A third side component is positioned between the first and second side components such that a third side component engagement portion cooperates a first side component engagement portion and that at least one other third side component engagement portion cooperates with a second side component engagement portion. The first side component is coupled to the third side component by inserting a first fastening mechanism in a first opening formed by the first side component engagement portion cooperating with the third side component engagement portion. The second side component is coupled to the third side component by inserting a second fastening mechanism in a second opening formed by the second side component engagement portion cooperating with the at least one other third side component engagement portion.

These illustrative aspects and embodiments are mentioned not to limit or define the invention, but to provide examples to aid understanding of the inventive concepts disclosed in this application. Other aspects, advantages, and features of the present invention will become apparent after review of the entire application.

### BRIEF DESCRIPTION OF THE DRAWINGS

FIG. 1 is a perspective view of a fully assembled circuit board assembly according to one embodiment.

FIG. 2 is a perspective view of a fully assembled circuit board assembly according to a second embodiment.

FIG. 3 is an exploded view of a modular vented circuit board enclosure according to one embodiment.

FIGS. 4A-4C are cross-sectional views of an enclosure according to one embodiment.

FIG. 5 is a front perspective view of a side component according to one embodiment.

FIG. 6 is a side perspective view of a side component according to one embodiment.

FIG. 7 is a top plan view of a side component according to one embodiment.

FIG. 8 is a bottom profile view of a side component according to one embodiment.

FIG. 9 is a bottom plan view of a side component according to one embodiment.

FIG. 10 is a top profile view of a side component according to one embodiment.

FIG. 11 is a perspective view of a corner component according to one embodiment.

FIG. 12 is a top plan view of a corner component according to one embodiment.

FIG. 13 is a bottom plan view of a corner component according to one embodiment.

FIG. 14 is a side plan view of a corner component according to one embodiment.

FIG. 15 is a perspective view of a face component according to one embodiment.

FIG. 16 is a top plan view of a face component according one embodiment.

FIG. 17 is a side plan view of a face component according one embodiment.

FIG. 18 is a second side plan view of a face component according one embodiment.

FIG. 19 is a diagram illustrating the airflow in the enclosure according to one embodiment.

FIG. 20 is an illustration depicting the enclosure mounted to an optical board in a vertical orientation according to one embodiment.

FIG. 21 is an illustration depicting the enclosure mounted to an optical board in a horizontal orientation according to one embodiment.

FIG. 22 is a perspective view of a side component according to a second embodiment.

FIG. 23 is a perspective view of the side component of FIG. 22 coupled to a guide according to one embodiment.

FIG. 24 is a perspective view of two side components coupled together to form a vent according to one embodiment.

### DETAILED DESCRIPTION

Certain aspects and embodiments of the present invention provide a modular circuit board enclosure that contains various components capable to coupling to each other to form an enclosure for housing various materials. Certain components can form a side (e.g. side component), a corner (e.g. corner component), and face (e.g. face component) of the enclosure. These components include protruding and/or recessed engagement portions that allow the components to couple together. For example, a protruding portion of a side component can cooperate with a recessed portion of a corner component, and receive a fastening mechanism, to couple the side component with the corner component. The protruding portion can cooperate with the recessed portion by, for example, overlaying the recessed portion or otherwise being located adjacent to the recessed portion, or by coupling in some fashion, such as by snap-fitting, slot-fitting, or socketing together. Multiple couplings in this manner can be repeated until a frame of the enclosure is formed.

Components according to some embodiments can be added to the frame of the enclosure to enclose the material stored therein. For example, a face frame filler component can be attached to an end of a face component to form a continuous surface across the face component. Filler plates may also fill across multiple components. Plates can attach to the ends of circuit boards, for example, to cover the circuit boards along at least one side of the enclosure. The enclosure can be formed when face component filler and plates are added to the frame of the enclosure, again where the frame is formed by connecting side components, corner components, and face components to each other.

In one embodiment, the components can cooperate to form one or more circuit board bays for housing printed circuit boards for a camera system. One or more side components can be connected to another side component to widen or add space to the enclosure for housing as many circuit boards as may be necessary for a particular camera application. The enclosure can contain connections for various circuitry devices. For example, circuit boards can attach to a backplane bus, which may include a backplane bus card, inside the enclosure.

Additional components can be added to the enclosure to meet an application's or user's needs. For example, handles can be attached to face components on opposite sides of the circuit board bays to permit an operator to grip and move the enclosure assembly. One or more mounted feet can also be attached to the enclosure to separate the enclosure from a surface.

Various embodiments herein are described using terms such as a “side,” “face,” “corner,” and “bottom,” among others These terms are used merely for convenience and should not limit the orientation of any component forming or within an enclosure. For example, a “side” component can be located on a “top” of an enclosure, depending on the orientation of the enclosure.

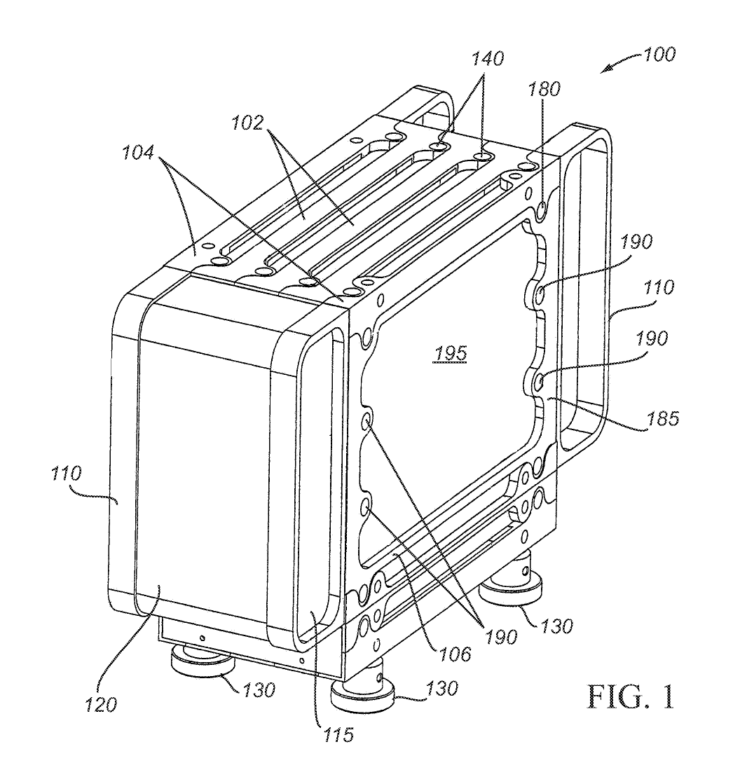

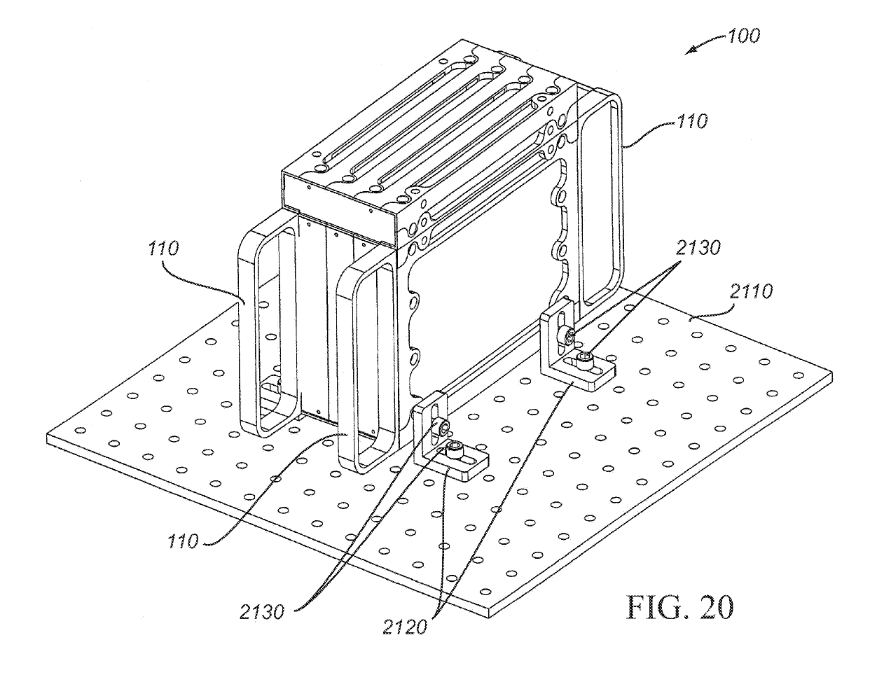

The following describes certain exemplary embodiments with reference to the drawings in which like numerals indicate like elements. FIGS. 1-3 illustrate one embodiment of a fully assembled modular circuit board enclosure. The modular circuit board enclosure 100 can be constructed using varying combinations of several components. These components can include one or more side components 102, one or more corner components 104, and one or more face components 106. The enclosure 100 may also include additional components, such as mounted feet 130 or mounting mechanisms 2120 and 2130, as shown in FIG. 20.

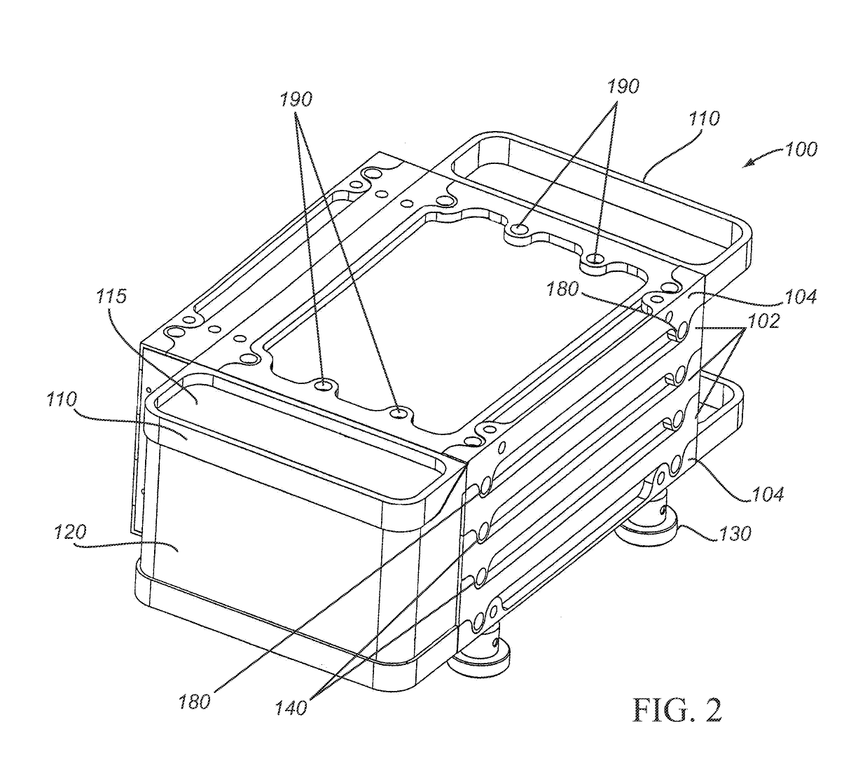

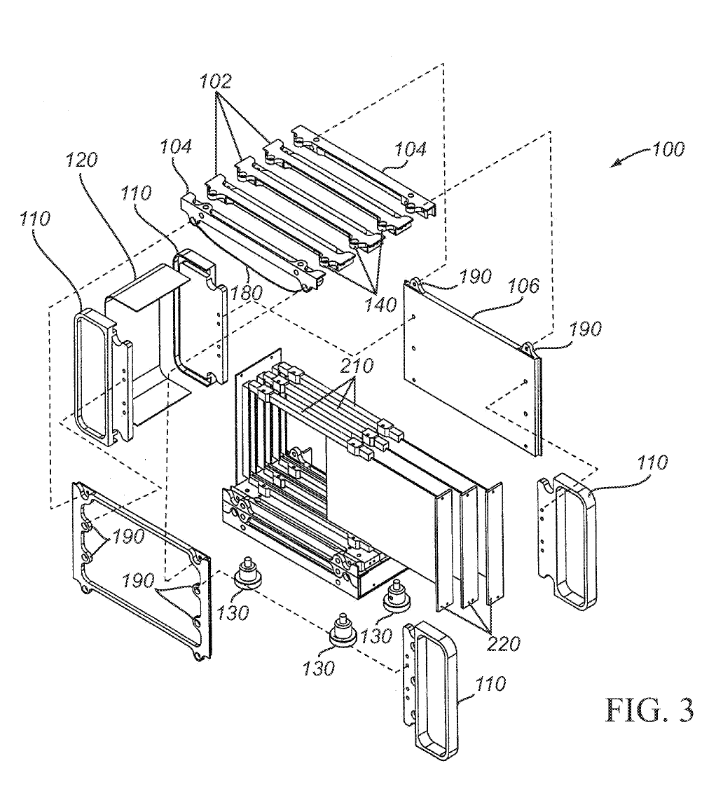

Enclosure 100 can encompass any type of material, matter, or product, including one or more card guides 210 for securing one or more printed circuit boards 220, as shown in the exploded view in FIG. 3. Enclosure 100 can be modified to vary in width, size, or orientation, depending on the user's needs. Such modifications include adding or removing one or more of the side components 102, corner components 104, or face components 106. For example, one or more side components 102 can be added to increase the width or length of the enclosure, depending on the orientation of the enclosure 100. For example, side components 102 can be added in the vertical orientation of enclosure 100, as shown in FIG. 1, to increase the width of the enclosure 100. Similarly, side components 102 can be added in the horizontal orientation, as shown in FIG. 2, to increase the length or height of the enclosure 100.

The enclosure 100 can be the same height as standard computer equipment to allow the enclosure 100 to be mounted within a standard computer rack-mount system. Furthermore, each side component 102 can have a 1 U height (1.719 inches), 2 U height (3.469 inches), or any other standard height to accommodate the use of standard size computer racks with the enclosure.

Some embodiments can allow removing, moving, or adding one or more additional components, including the mounted feet 130. FIG. 1 depicts the mounted feet 130 affixed to the bottom of the enclosure 100 to position the enclosure 100 in a vertical orientation. The mounted feet 130 can be inserted into a side component 102 or the corner component engagement portions 180 to affix the mounted feet 130 to the bottom of the enclosure 100. In some embodiments, the mounted feet 130 can also be affixed to a face component 106 of the enclosure 100 by inserting the mounted feet into a face component engagement portion 190 of the face component 106, or otherwise. The face component engagement portions 190 may be included on the face frame 185 or on the face frame filler component 195, as shown in FIG. 1.

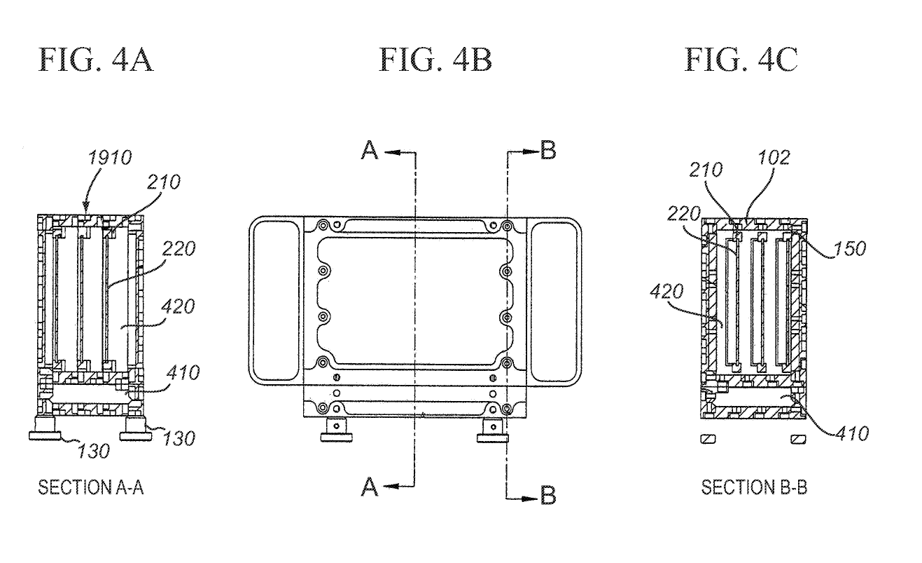

FIGS. 4A-4C provide a cross-sectional view that includes a more detailed overview of the enclosure 100 interior. FIG. 4A is a cross-sectional view at Line A in FIG. 4B that shows the circuit board bay 420 housing circuit boards 220. Circuit boards 220 can be secured by card guides 210. The number of circuit boards 220, the number of card guides 210, the type of circuitry, or other matter enclosed in the circuit board bay 420 can vary depending on the user's needs.

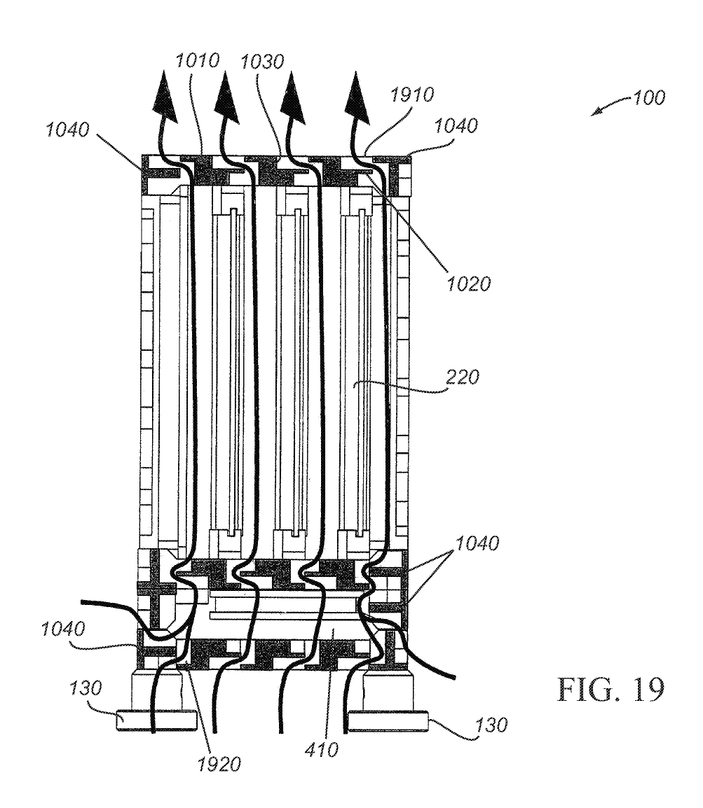

The enclosure 100 can also include a fan bay 410, as shown in FIG. 19, to house a fan or other cooling apparatus. In one embodiment, the fan bay 410 can be constructed with side components 102, corner components 104, and face components 106 in similar fashion to the enclosure 100. In another embodiment, a manifold tray can attach to a side component, corner component, or face component of the enclosure 100 to house a fan or other cooling mechanism. Fan bay 410 can preserve valuable space usually used by bulky fan modules, and it can alleviate the need to position the enclosure 100 near an external fan or cooling source. In some embodiments, a face component 106 includes an opening for receiving and coupling to a fan.

FIG. 4C is a cross-sectional view from Line B in FIG. 4B and shows additional details regarding the disclosure. This view shows card guides 210, which may be included within the enclosure to guide the printed circuit boards 220 into the circuit board bay 420. The card guides 210 can receive the circuit boards 220 and maintain the circuit boards 220 in a fixed position.

FIG. 4C further illustrates a threaded insert 150 located within a side component 102. In some embodiments, the threaded insert 150 can ease manufacturing in cast or molded materials to the enclosure 100. The threaded insert 150 can be formed from any material, including comparatively hard material so that the threads do not wear out prematurely.

Components of the enclosure 100 according to some embodiments cooperate together to provide a modular enclosure. The components together provide the enclosure 100 for any type of material, matter, or product, including computer circuitry, such as one or more printed circuit boards. The components can include side component 102, corner component 104, and face component 106. The following describes each of these components in greater detail.

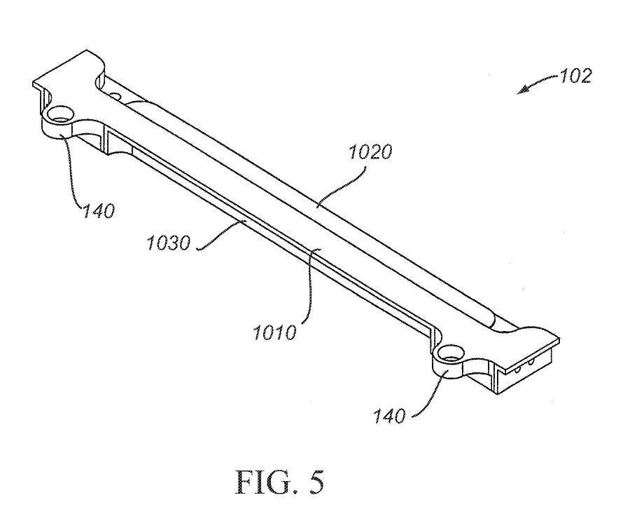

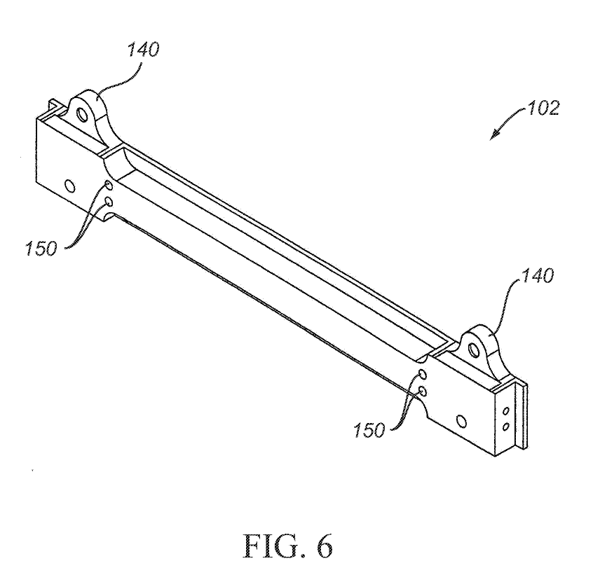

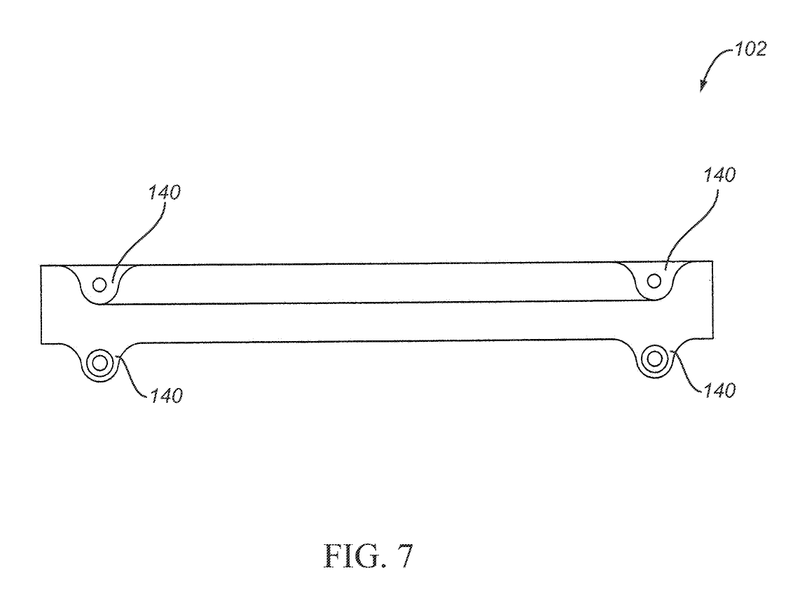

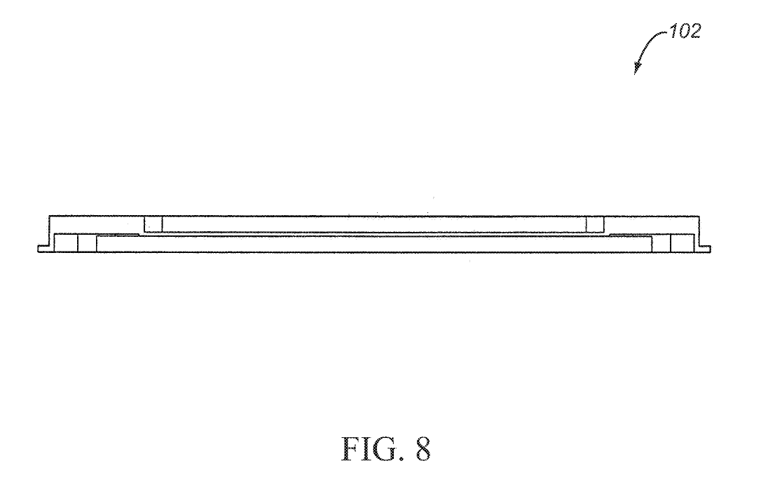

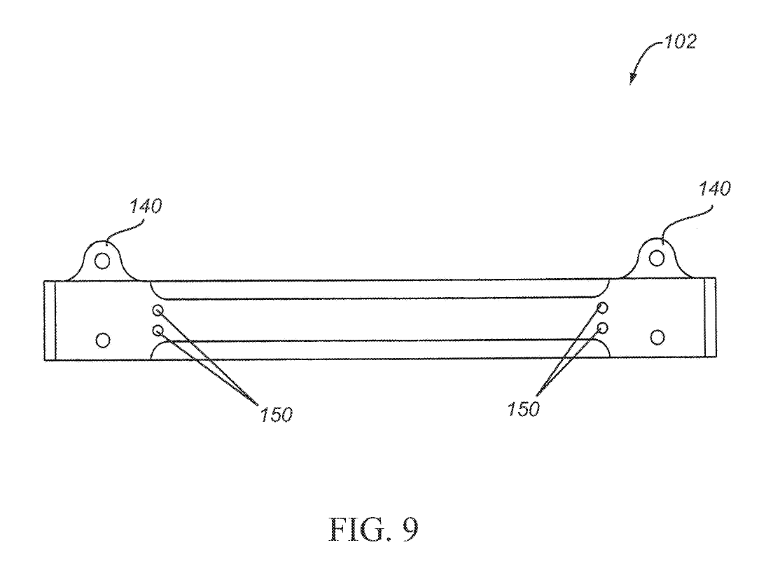

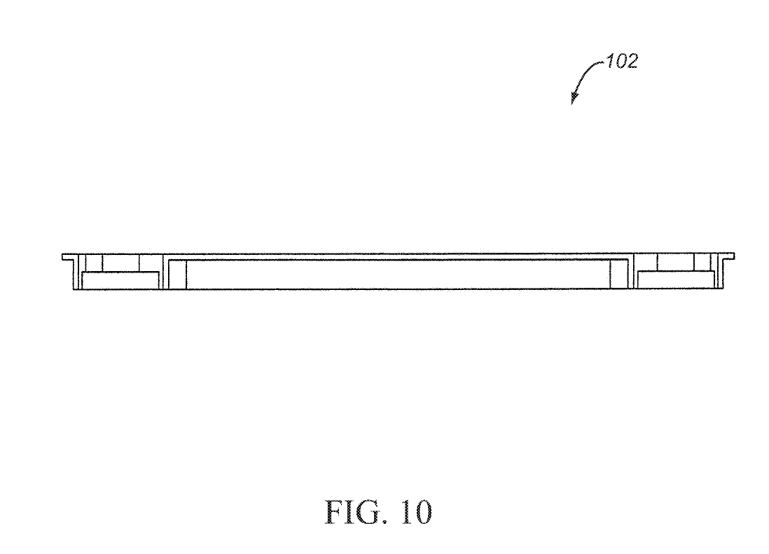

A side component 102, according to one embodiment of the invention, is depicted in FIGS. 5-10. Side components according to various embodiments, however, can vary in size, shape, or design. The side component 102 depicted includes an elongated bar configuration with a first and second side, and a first and second end. The side component 102 includes on the first side a pair of protruding engagement portions 140 positioned adjacent to the ends of the side component 102. On the second side opposite the first side, the side component 102 includes a pair of recessed portions. The protruding engagement portions 140 of one side component 102 cooperate and engage with surfaces defining a corresponding recess of an adjoining side component so that side components can be stacked. In some embodiments, the protruding engagement portions 140 include one or more protrusions having openings extending through the protrusions.

The side component 102 can include a first portion 1010 and a second portion 1020, as shown in FIG. 5. The second portion 1020 can be offset at a distance relative to the first portion 1010. The side component 102 can be configured with a “Z-shaped” configuration when viewed in cross-section (as shown for example in FIG. 19) so that the first portion 1010 and the second portion 1020 extend in opposite directions from a vertically extending stepped body portion 1030 connecting the first and second portions 1010 and 1020.

Vent openings in the enclosure 100 can be created from the second portion 1020 of a side component extending toward the first portion 1010 of an adjacent side component 102 or corner component 104 but on a different plane from that of the first portion 1010. The result is a stepped or undercut appearance so that a vent opening exists. FIG. 19 depicts such openings as vents 1910 and 1920. The vents 1910 and 1920 can be holes or openings to permit airflow into and out of the enclosure 100 to control the temperature therein. The arrows shown in FIG. 19 illustrate examples of potential paths of airflow through the enclosure 100.

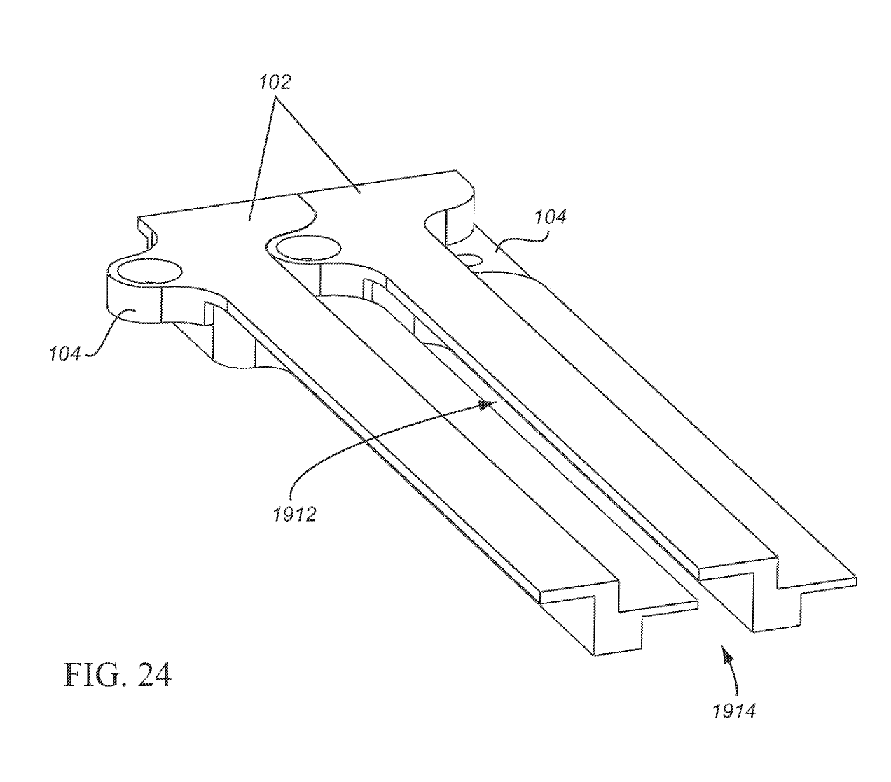

FIG. 24 depicts two side components coupled together to form a vent 1910 according to one embodiment. The side components 102 can be configured to form the vent 1910 having a Z-shaped cross-section and having an inlet 1912 and an outlet 1914. The vent 1910 can provide channel for airflow into and out of the enclosure 100. Air can, for example, flow through the channel that has a Z-shaped cross section to enter and/or exit the enclosure 100. In some embodiments, the vent 1910 has varying widths along the channel. For example, the inlet 1912 can be narrower then the outlet 1914.

The enclosure 100 benefits from having vent openings created as part of the assembly of the enclosure 100 rather than after the manufacturing process, which may require drilling holes to permit air to flow into and out of the enclosure. Furthermore, embodiments of vents 1910 and 1920 can prevent a user's finger or other body extremity to be received in an inner area of the enclosure 100, which may house dangerous or high voltage components, but permit airflow through the enclosure 100. In other embodiments, an enclosure can be provided without vents 1910, 1920, or vents 1910, 1920 may be relatively large.

A corner component 104, according to some embodiments, includes a side flange 1100 for providing a surface to cover the area between connected components. The side flange 1100 can prevent debris and the like from entering the enclosure, while allowing sufficient airflow to pass through the side flange 1100 for controlling the temperature inside of the assembly. The side flange 1100 extends perpendicular to the central axis of the corner component 104. In some embodiments, a first side of a side component 102 contains a flange to cover the area between another adjacent component. The corner component 104 has an elongated form including one or more corner component engagement portions 180. The corner component 104 depicted in FIG. 19 has a “T-shaped” cross-section 1040. In some embodiments, as shown in FIG. 19, the corner component 104 includes a vent formed by the corner component 104 coupled to a side component 102. An enclosure having the vent formed by the corner component 104 coupled to a side component 102 may or may not include other vents, such as a vent formed by side components 202 coupled together.

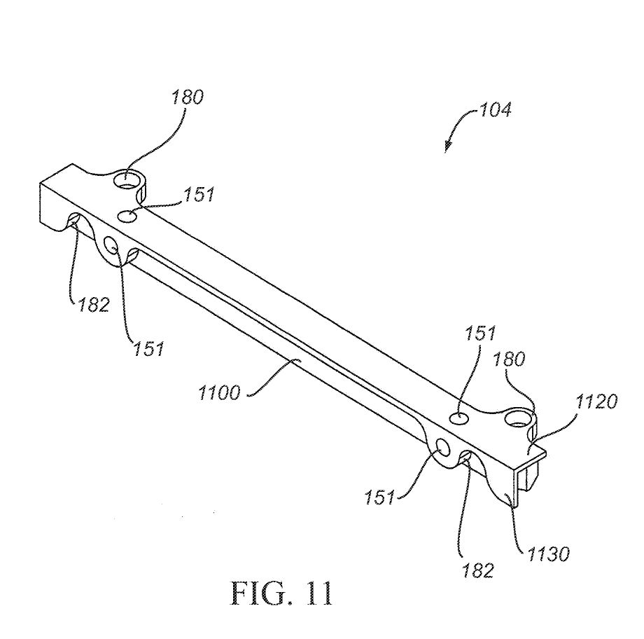

In one embodiment, the corner component engagement portions 180 each include one or more protrusions capable of having an opening extending therethrough. In the embodiment of FIG. 11, the corner component 104 is configured with four engagement portions 180, a pair on each side of the surfaces abutting to form a 90° corner angle. In other embodiments, the corner of corner component 104 is formed at an angle greater than or less than 90°. The corner angle may be formed by an end of a first portion 1120 and a second portion 1130. The second portion 1130 is offset at a distance relative to the first portion 1120, as shown in FIG. 11.

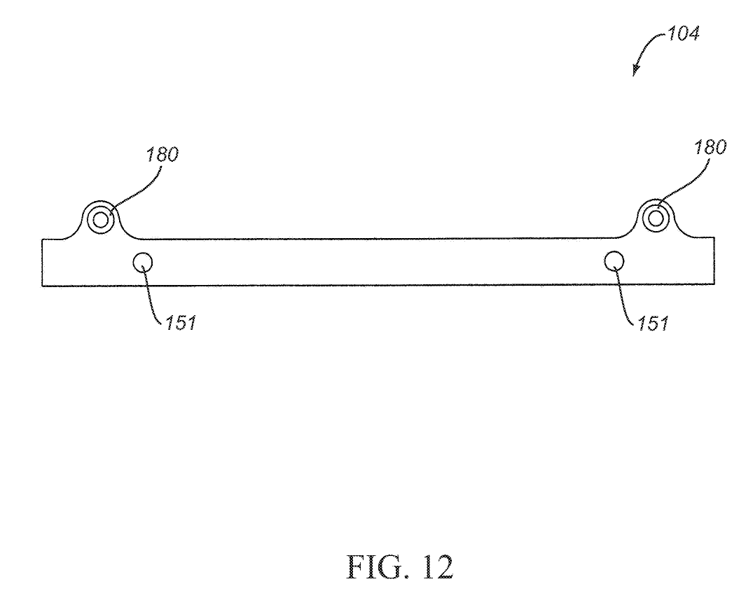

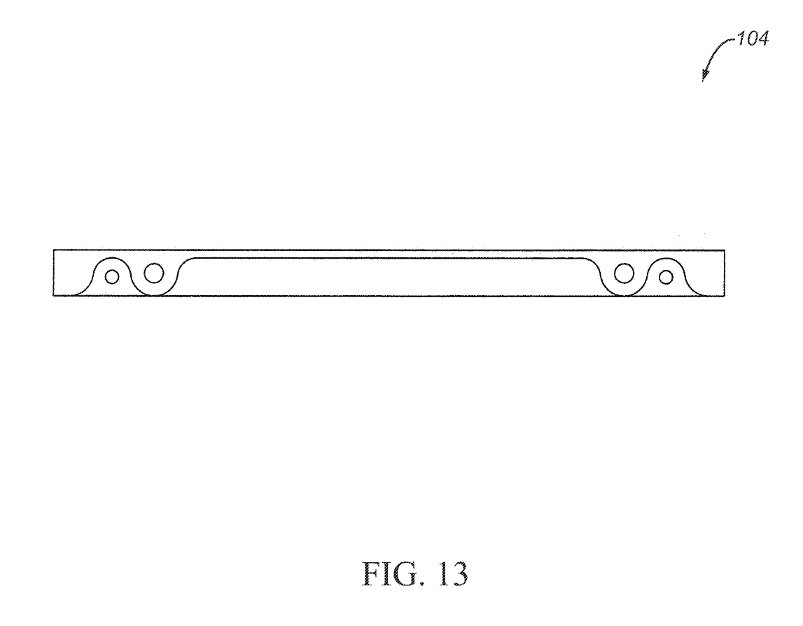

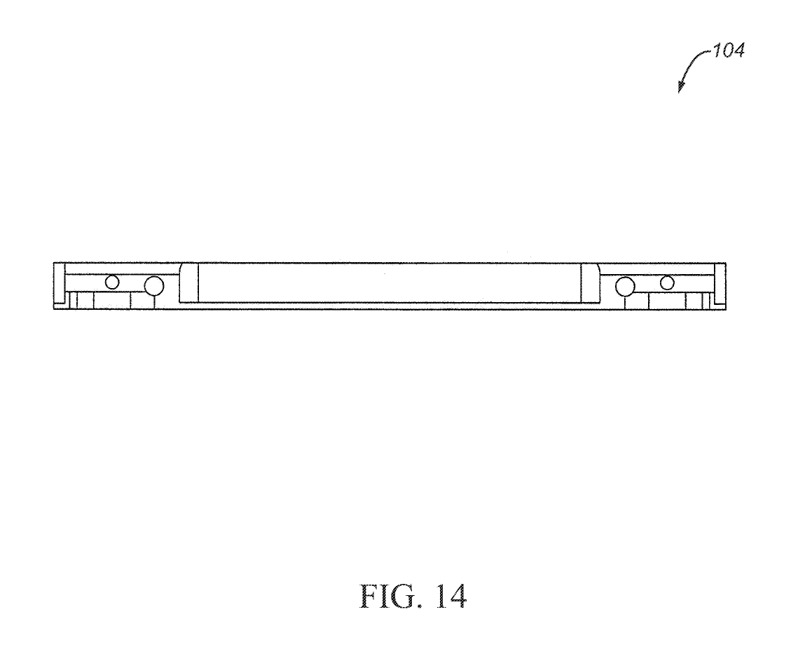

As with the side component 102, the engagement portions 180 are spaced apart and positioned towards the ends of the corner component 104 that is elongated, as depicted for example in FIGS. 12-14. This spacing of the pairs of engagement portions 180 can provide stability for the assembly in coupling the corner components 104 with other components. Obstruction of the ventilation openings can be avoided by providing the engagement portions 180 at the ends. In addition, the corner component 104 can be configured with two recessed portions 182 positioned adjacent to the engagement portions 180, as shown in FIG. 11.

The engagement portions 180 can be configured for engaging the engagement portion of another component, such as a side component 102, a face component 106, or another corner component 104, by fastening mechanisms such as screws, bolts, glue, or nails. For example, a corner component engagement portion 180 can be connected to a engagement portion 140 by inserting a bolt through aligned engagement portions 140 and 180, and securing the bolt with a nut.

A corner component 104 according to some embodiments includes at least one corner component opening 151 to allow the corner component 104 to couple to other components, such as mounted feet, fastening hinges, or mounting mechanisms including brackets. In some embodiments, the corner component opening 151 is offset by one inch from either end of the corner component 104.

In some embodiments, the first portion 1120 or the second portion 1130 of the corner component 104 extends to include the face component 106 and to form an integral or solid component. The portion of the corner component 104 that is not joined to the face component 106 can be attached to a side component 102 or other component.

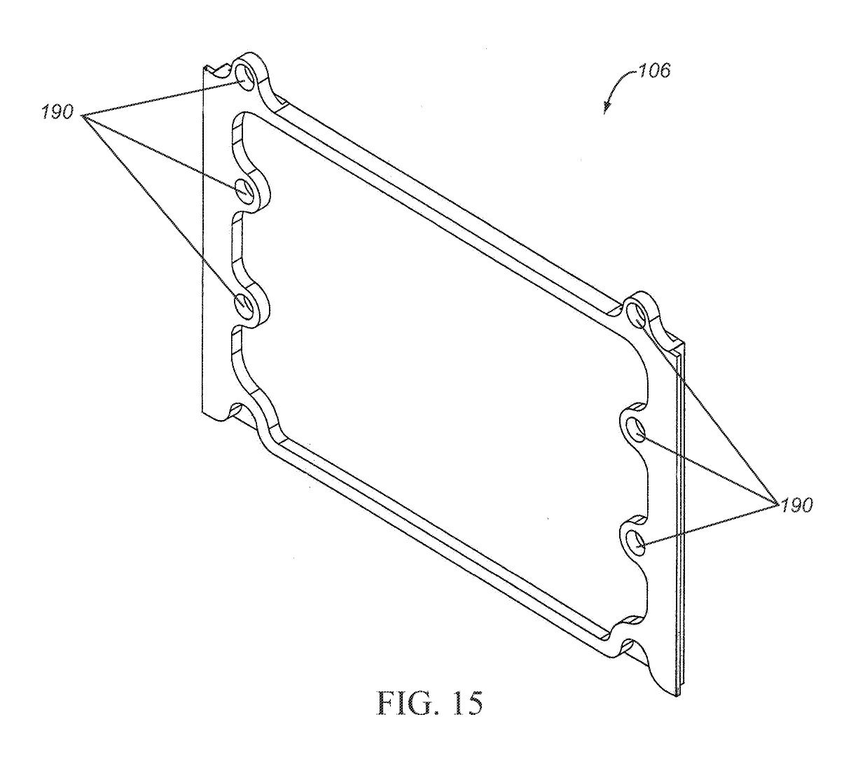

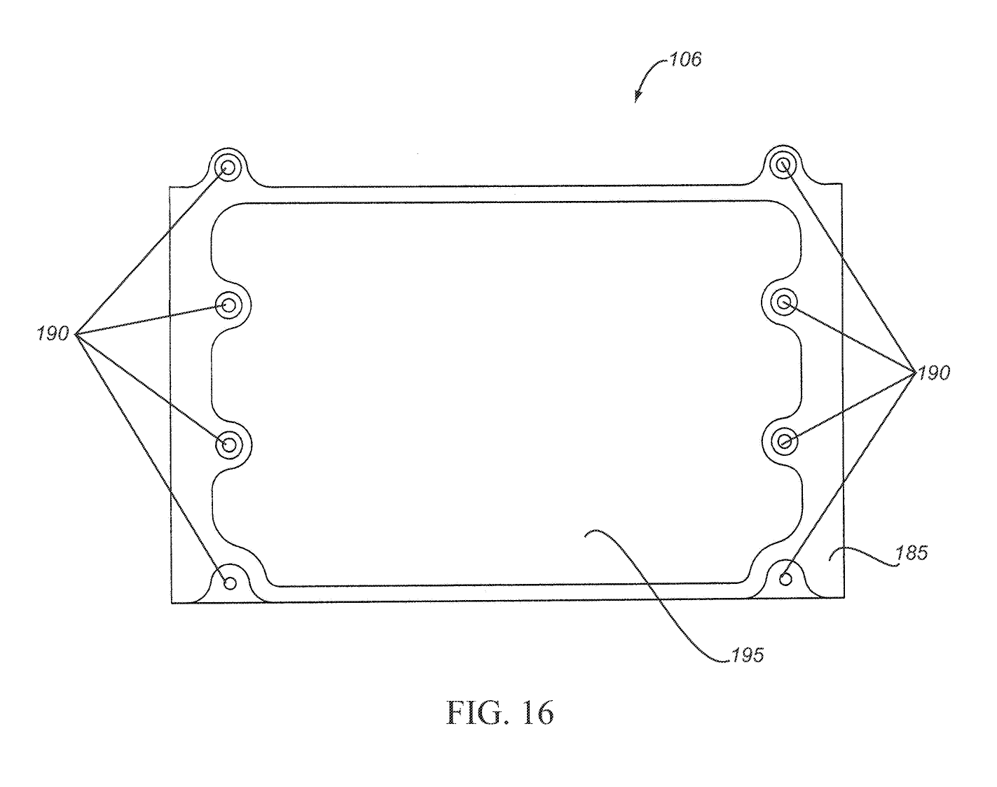

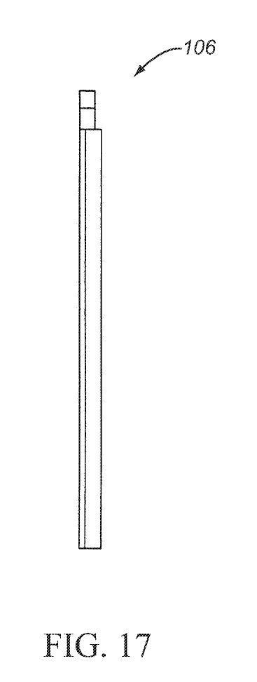

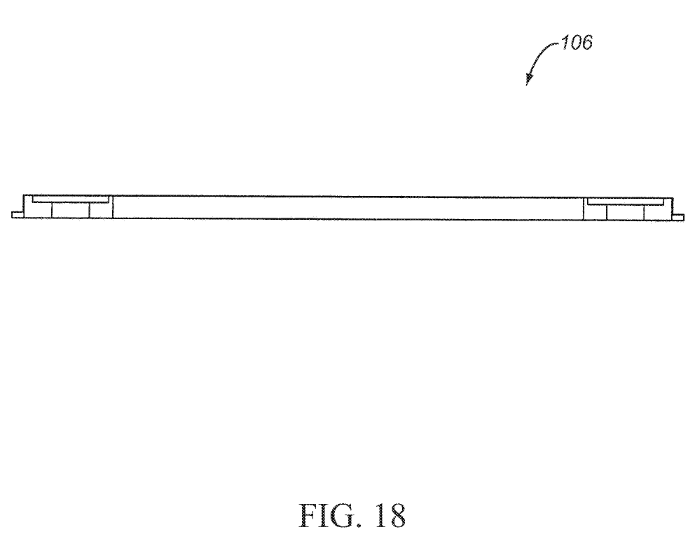

Face components 106, as shown in FIGS. 15-18, can provide a covering for the sides of the enclosure 100. The face component 106 includes a face frame 185 and can include a face frame filler component 195. In some embodiments, the face frame 185 has a rectangular or square configuration for attaching to the periphery of at least one side of the enclosure 100. The face frame filler component 195 can attach to the face frame 185 to create an integral piece for covering the sides of the enclosure 100. The face frame filler component 195 can be attached to the face frame 185 by various fasteners, such as bolts, screws, nails, or glue. Alternatively, the face component 106 can be comprised of one integral or solid element. In one embodiment, the integral or solid face component 106, or the face frame filler component 195, includes a company logo or other writings printed thereon.

Face components 106 according to some embodiments, as shown for example in FIGS. 15-18, can include a face component engagement portion 190 for engaging with another component, such as a side component 102, corner component 104, or another face component 106. The face component engagement portion 190 can, in some embodiments, include one or more protrusions including openings extending therethrough. The openings of the face component 106, and openings in the engagement portions of other components, can receive a screw, bolt, or any other type of fastener to couple the component to other components to form the frame of the enclosure 100. For example, a face component engagement portion 190 can be coupled to a corner component engagement portion 180 by inserting a bolt, or other fastening mechanism, through aligned engagement portions 180 and 190, and securing the bolt with a nut.

FIGS. 1-3 depict the enclosure 100 coupled to handles 110. The handles 110 can attach, for example, to face components 106 on opposite sides of the circuit board bays. The handles 110 may also attach to corner component openings 151 of opposing corner components 104 so that the handles 110 are arranged in spaced opposition to one another. In some embodiments, such as the embodiment shown in FIG. 20, such an arrangement of the handles 110 can permit an operator to grip the handles to move the enclosure 100. In other embodiments, the handles 110 can be used in conjunction with handle filler 115 and a handle connecting portion 120 to enclose one or more sides of the enclosure 100. In some embodiments, handle filler 115 attaches to the handle to create one integral or solid handle 110. The handle filler 115 can be perforated to permit air to flow into or out of the enclosure 100. A handle connecting portion 120 may be positioned between handles 110.

The handle filler 115 and handle connecting portion 120 can be constructed out of any material suitable for sufficiently enclosing the area to a user's specifications. Examples of such materials include extruded aluminum, plastic, or composite material. The handles 110 may also include a handle engagement portion that includes one or more protrusions having openings for receiving fasteners, such as screws or bolts, to couple to the corner components 104 or face components 106.

The various embodiments provide an enclosure that can be attached or positioned in a number of different ways. The enclosure can be equipped with mounted feet 130 to provide standing enclosure. The mounted feet 130 can be attached to position the enclosure 100 either with a vertical orientation (as shown in FIG. 1), or a horizontal orientation (as shown in FIG. 2).

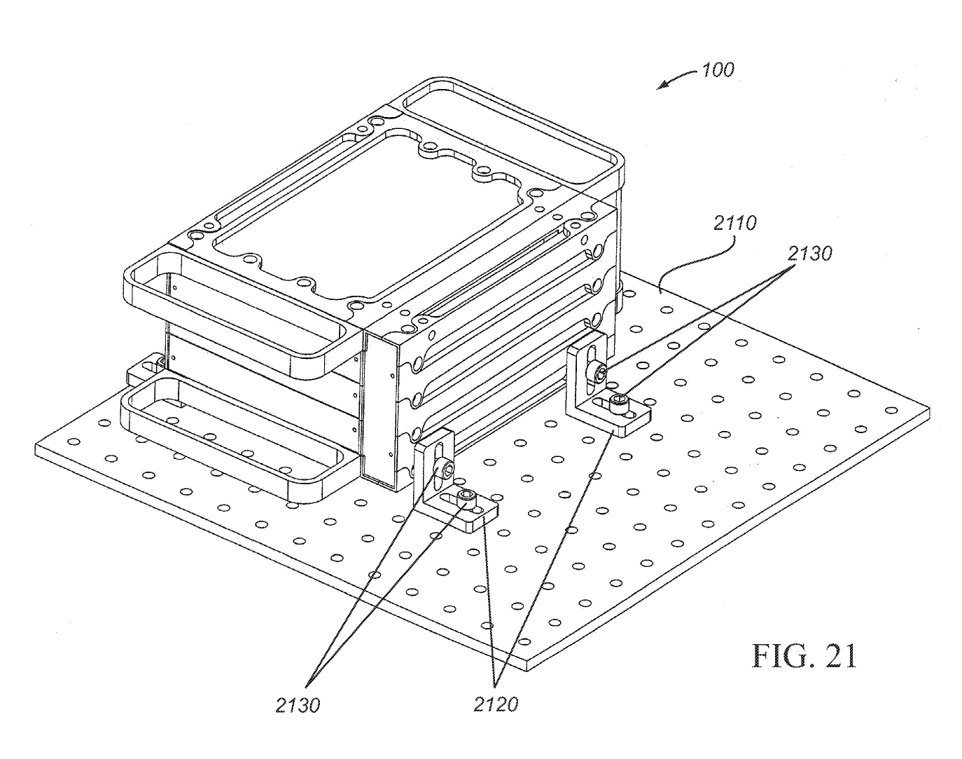

Moreover, attachment mechanisms can be attached to the enclosure to permit the enclosure to be mounted to a standard camera mounting system, or any other type of shelving or surface. These attachment mechanisms can include mounting mechanisms 2120, such as brackets, for hanging the enclosure 100 or for securing the enclosure 100 to a surface, as shown in FIGS. 20-21. The attachment mechanism cooperates with openings 151 of a corner component 104 to secure the enclosure 100.

FIG. 20 shows the enclosure 100, including mounting mechanisms 2120, secured to an optical mounting board 2110 via mounting mechanisms 2130, such as bolts, inserted into the mounting mechanisms 2120 (in a vertical orientation, for example). FIG. 21 shows the same concept as in FIG. 20, but utilized to align the enclosure in a horizontal orientation (with the enclosed circuitry or circuit boards in a horizontal orientation). In addition to mounted feet 130 or mounting mechanisms 2120 used to position the enclosure in a desired location, the enclosure 100 can also be mounted to another enclosure by reverse fitting two side components together.

The enclosure 100 of the various embodiments provides a flexible way to add, remove, or access circuit boards for testing, maintenance, or other purposes. In some embodiments, a user can remove a face frame 185 to access one or more printed circuit boards 220 housed within the enclosure 100. A user may access a second printed circuit board 220 located behind a first printed circuit board 220 by removing the face frame 185 and the first printed circuit board 220. As stated above, the face component 106 may include a face frame 185, and may also include the face frame filler component 195. Alternatively, the face frame 185 can be affixed to the enclosure 100 without a face frame filler component 195, which may be useful in the event that the user requires frequent access to the contents of enclosure 100.

In other embodiments, the enclosure 100 can be separated at a point where side components 102 are joined or, for example, where a side component 102 attaches to a corner component 104. Fastening mechanisms used to join side components 102 to one another or to a corner component 104 may be decoupled to permit the enclosure 100 to separate and allow access to the inside of the enclosure 100. Additional structures that are used to cover at least one side of the enclosure 100, such as the fan bay 410 and handles 110 with handle connecting portion 120, may also be decoupled to permit the enclosure 100 to be separated.

The various embodiments describe an enclosure, and accompanying components, which can be comparatively easy to manufacture. Due to the simple configuration of each component (the side components 102, the corner components 104, and the face components 106), each component may be efficiently created using standard off-the-shelf extruded aluminum. Once inserted into a bar-feed, a typical CNC machine could efficiently manufacture each of the components by tracing the outlines of each component, as shown in the accompanying figures.

Further, due to the size and shape of the components, the components can be manufactured from standard off-the-shelf extruded aluminum with minimal waste, which provides a more environmentally friendly and more cost-efficient solution for manufacturing enclosures. In addition to extruded aluminum, the enclosure 100, and its associated components, can be manufactured from any material, such as metals, concrete, wood, glass, plastic, or any other natural or synthetic material. In addition, other manufacturing techniques such as molding, casting, and stamping can be employed to form the components of the enclosure 100.

As stated above, the enclosure 100 may also contain threaded inserts 150 that can be utilized to provide additional strength to the overall enclosure 100 and each individual component. The threaded insert 150 may also permit ease of manufacturing in embodiments where the side components 102, corner components 104, or face components 106 are constructed from, for example, cast or molded materials. A threaded insert 150 can be made from a material stronger than that of the material comprising the enclosure 100 and individual components. In some embodiments, the threaded insert 150 is inserted into a small hole located at any location in a component of the enclosure 100. In other embodiments, the threaded insert 150 can be located in one or more areas of the enclosure 100 that are expected to receive environmental stresses or other forces to provide additional protection for those areas.

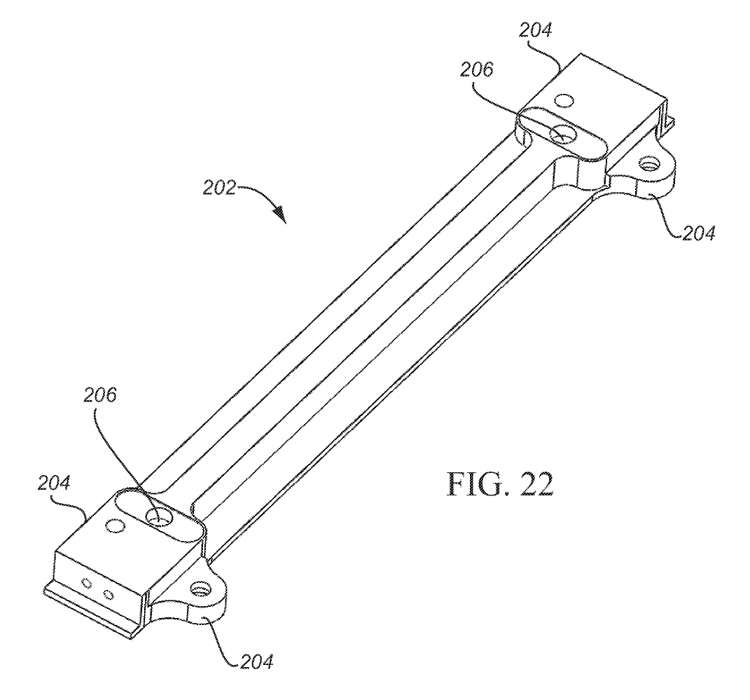

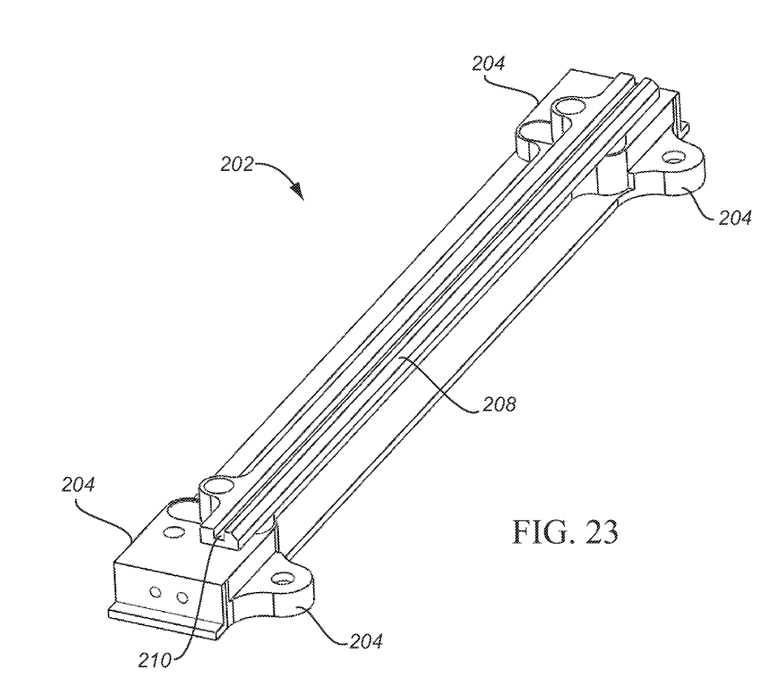

Although side components 102 according to various embodiments of the present invention include threaded inserts 150, side components 102 according to other embodiments include openings that are off-set from a longitudinal center line. The openings can allow the side component 102 to couple to a guide, such as a guide for a circuit board. In other embodiments, a side component is configured with openings that are not off-set. FIGS. 22-23 depict an embodiment of a side component 202 that is capable of cooperating with other components for coupling to them. The side component 202, for example, includes engagement portions 204 that can cooperate with engagement portions of other components (e.g. another side component or a corner component) to couple together. Engagement portions 204 can include one or more of a protruding engagement portion and a recessed engagement portion. The side component 202 also includes openings 206. The openings 206 can be configured to receive part of a guide 208, such as a circuit board guide, to couple the guide 208 to the side component 202. The openings 206 are positioned along a longitudinal center line to allow for a more centric coupling configuration with the guide 208, as shown in FIG. 23, even though guide 208 includes a track 210 that is offset from the longitudinal center line. The track 210 can receive a circuit board, for example, which may include electrical components such that the track 210 positioned off-set from a longitudinal center line is desirable to provide sufficient space for the electrical components.

Guides according to various embodiments can have various shapes and configurations. For example, a track can be offset from the longitudinal center line on an opposite side than that shown in FIG. 23, even though the guide 208 couples to the side component 202 using openings 206 along the longitudinal center line.

Although specific embodiments and examples have been described herein, such disclosure is not intended to limit the scope of the invention. The size and configuration of the enclosure 100 and the components that are used to shape it may vary while maintaining the spirit and scope of the embodiments. For example, different combinations and numbers of side components 102, corner components 104, and face components 106 may be used to create enclosures of varying lengths and widths. Thus, in addition to claiming the subject matter literally as defined in the appended claims, all modifications, alterations, and equivalents to which the applicant is entitled by law, are herein expressly reserved by the following claims.

What is claimed is:

1. A modular enclosure for housing a circuit board, the modular enclosure comprising:
a side component having a side component engagement portion;
a corner component having a first corner component engagement portion and a second corner component engagement portion, the first corner component engagement portion capable of cooperating with the side component engagement portion; and
a face component having a face engagement portion capable of cooperating with the second corner component engagement portion.

2. The modular enclosure of claim 1, wherein at least part of the side component is configured to cooperate with at least part of a second side component.

3. The modular enclosure of claim 1, further comprising:
a first plurality of side components, a first one of the first plurality of side components being coupled to the side component;
a second corner component coupling a second one of the first plurality of side components to a second face component;
a third corner component coupling the second face component to a first one of a second plurality of side components; and
a fourth corner component coupling a second one of the second plurality of side components to the face component.

4. The modular enclosure of claim 1, wherein the first corner component engagement portion and the side component engagement portion are configured to receive a fastening mechanism to couple the corner component with the side component,
wherein the second corner component engagement portion and the face engagement portion are configured to receive a second fastening mechanism to couple the face component with the corner component.

5. The modular enclosure of claim 1, wherein the side component engagement portion comprises a recessed portion,
wherein the first corner component engagement portion comprises a protruding portion capable of cooperating with the recessed portion.

6. The modular enclosure of claim 1, wherein the face component engagement portion comprises a protruding portion,
wherein the second corner component engagement portion comprises a recessed portion capable of cooperating with the protruding portion.

7. The modular enclosure of claim 1, further comprising:
a circuit board bay configured to receive the circuit board;
a plate configured to be coupled to an end of the circuit board when the circuit board is received by the circuit board bay, wherein the plate is configured to enclose at least one side of the circuit board bay;
a handle coupled to a handle connecting portion to enclose at least one side of the circuit board bay; and
a face frame filler component coupled to the face component to enclose at least one side of the circuit board bay.

8. The modular enclosure of claim 1, wherein the circuit board is part of a camera system.

9. The modular enclosure of claim 1, wherein the circuit board comprises a fan for cooling at least part of the circuit board.

10. The modular enclosure of claim 1, further comprising a manifold tray coupled to at least one side component, face component, or corner component.

11. The modular enclosure of claim 1, further comprising a mounting mechanism coupled to at least one corner component opening of the corner component.

12. The modular enclosure of claim 11, wherein the mounting mechanism comprises a mounting bracket capable of aligning a circuit board bay in a vertical or a horizontal orientation.

13. The modular enclosure of claim 1, further comprising:
a second corner component coupled to a second side component and coupled to a second face component,
wherein the second side component is at least one of:
coupled to the side component; or
coupled to a third side component positioned between the side component and the second side component.

14. A modular enclosure comprising:
a first side component having a first engagement portion;
a second side component having a second engagement portion, the second engagement portion cooperating with the first engagement portion to couple the first side component with the second side component,
wherein the first side component coupled to the second side component forms a vent for allowing airflow into and out of the enclosure, the vent having a Z-shaped cross-section.

15. The modular enclosure of claim 14, further comprising:
a corner component having a first corner component engagement portion and a second corner component engagement portion,
wherein the first corner engagement portion cooperates with part of the first side component to couple the corner component to the side component,
wherein the second corner component engagement portion cooperates with part of a face component to couple the corner component to the face component.

16. The modular enclosure of claim 15, wherein the first corner engagement portion cooperates with the part of the first side component to couple the corner component to the side component by being positioned adjacent to the part of the first side component and by receiving a first fastening mechanism,
wherein the second corner component engagement portion cooperates with the part of the face component to couple the corner component to the face component by being positioned adjacent to the part of the face component and by receiving a second fastening mechanism.

17. The modular enclosure of claim 14, wherein the first side component couples to a corner component to form a second vent, the second vent having a Z-shaped cross-section.

18. The modular enclosure of claim 14, wherein the first engagement portion comprises a protruding portion and the second engagement portion comprises a recessed portion capable of cooperating with the protruding portion.

19. The modular enclosure of claim 14, wherein the modular enclosure is used in a camera system.

20. A method for customizing a size of a modular enclosure, the method comprising:
decoupling a first side component from a second side component of the modular enclosure;
positioning a third side component between the first side component and the second side component, such that a third side component engagement portion cooperates with a first side component engagement portion and that at least one other third side component engagement portion cooperates with a second side component engagement portion;
coupling the first side component to the third side component by inserting a first fastening mechanism in a first opening formed by the first side component engagement portion cooperating with the third side component engagement portion; and
coupling the second side component to the third side component by inserting a second fastening mechanism in a second opening formed by the second side component engagement portion cooperating with the at least one other third side component engagement portion.

21. The method of claim 20, further comprising:
coupling a plurality of mounted feet to the modular enclosure;
orienting the modular enclosure in at least one of a vertical position or in a horizontal position using the mounted feet.

22. The method of claim 20, further comprising:
decoupling a face component from a corner component;
decoupling the corner component from the first side component;
positioning a fourth side component between the corner component and the first side component;
coupling the fourth side component to the corner component; and
coupling the fourth side component to the first side component.
